(19) United States
(12) Patent Application Publication
(10) Pub. No.: US 2025/0266390 A1
(43) Pub. Date: Aug. 21, 2025

(54) LASER ASSISTED BONDING DEVICE AND METHOD FOR BONDING A SEMICONDUCTOR DIE ONTO A SUBSTRATE

(71) Applicant: STATS ChipPAC Pte. Ltd., Singapore (SG)

(72) Inventors: DongSam PARK, Incheon (KR); TaeKeun LEE, Incheon (KR); HyungSuk MIN, Incheon (KR)

(21) Appl. No.: 19/055,542

(22) Filed: Feb. 18, 2025

(30) Foreign Application Priority Data
Feb. 21, 2024 (CN) 202410192561.X

(51) Int. Cl. H01L 23/00

(52) U.S. Cl. CPC H01L 24/75; H01L 24/81; H01L 2224/75263; H01L 2224/75312; H01L 2224/75983; H01L 2224/81203; H01L 2224/81224; H01L 2224/81815; H01L 2924/401

(57) ABSTRACT

A laser assisted bonding device and a method for bonding a semiconductor die onto a substrate are provided. The laser assisted bonding device comprises: a compression bonding mechanism, wherein the compression bonding mechanism comprises: a compression base comprising a vacuum passage extending through the compression base and fluidly connected with a vacuum source; and a compression head attached to the compression base, wherein the compression head comprises a plurality of blocks, and a plurality of grooves separating the plurality of blocks from each other and being fluidly connected with the vacuum passage, and wherein a size of a block decreases with a distance of the block to the vacuum passage; and a laser source configured for emitting a laser beam to heat solder bumps between the semiconductor die and the substrate.

### FIELD

The present application generally relates to semiconductor technology, and more particularly, to a laser assisted bonding device and a method for bonding a semiconductor die onto a substrate using a compression bonding mechanism.

### BACKGROUND OF THE INVENTION

Semiconductor packaging is one of the most important parts of semiconductor manufacturing and design. The semiconductor packaging process affects power, performance, cost and basic functionalities of all semiconductor chips. Typically, semiconductor dice are first fabricated in wafer level and then each semiconductor die may be attached onto a package substrate to form an integrated semiconductor device.

The attaching process of the semiconductor die can be conducted by a bonding device, for example. During the bonding process, the bonding device picks up a semiconductor die using vacuum and then places the semiconductor die on a package substrate. A heating process may be conducted to heat solder bumps beneath the semiconductor die during the bonding process, which allows the solder bumps to form electrical connection between the semiconductor die and the package substrate. However, it is noted that a temperature distribution across the semiconductor die during the heating process is in lack of uniformity, which induces warpage issues and adversely affects the performance of the semiconductor device so produced.

Therefore, a need exists for further improvement of a bonding device and a method for bonding a semiconductor die onto a substrate.

### SUMMARY OF THE INVENTION

An objective of the present application is to provide a laser assisted bonding device and a method for bonding a semiconductor die onto a substrate with reduced warpage issues.

According to an aspect of the present application, a laser assisted bonding device is provided. The laser assisted bonding device comprises: a compression bonding mechanism configured for picking up a semiconductor die and pressing the semiconductor die against a substrate, wherein the compression bonding mechanism comprises: a compression base comprising a vacuum passage extending through the compression base and fluidly connected with a vacuum source; and a compression head attached to the compression base, wherein the compression head comprises a plurality of blocks distributed across the compression head and being in contact with the semiconductor die when the semiconductor die is picked up or pressed against the substrate by the compression bonding mechanism, and a plurality of grooves separating the plurality of blocks from each other and being fluidly connected with the vacuum passage to form vacuum in the plurality of grooves, and wherein a size of a block of the plurality of blocks decreases with a distance of the block to the vacuum passage; and a laser source configured for emitting a laser beam that passes through the compression bonding mechanism to heat solder bumps between the semiconductor die and the substrate.

According to another aspect of the present application, a method for bonding a semiconductor die onto a substrate using a compression bonding mechanism is provided, wherein the compression bonding mechanism comprises a compression base comprising a vacuum passage extending through the compression base and fluidly connected with a vacuum source, and a compression head attached to the compression base, wherein the compression head comprises a plurality of blocks distributed across the compression head, and a plurality of grooves separating the plurality of blocks from each other and being fluidly connected with the vacuum passage to form vacuum in the plurality of grooves, and wherein a size of a block of the plurality of blocks decreases with a distance of the block to the vacuum passage. The method comprises: picking up the semiconductor die via the compression bonding mechanism by activating the vacuum source and applying vacuum in the plurality of grooves through the vacuum passage, wherein the compression head is in contact with the semiconductor die; displacing the compression bonding mechanism to place the semiconductor die on the substrate; pressing the semiconductor die against the substrate while vacuum is maintained in the plurality of grooves, wherein the compression head is in contact with the semiconductor die; and emitting a laser beam to the semiconductor die through the compression bonding mechanism via a laser source to heat solder bumps between the semiconductor die and the substrate.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain the principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIGS. 1A to 1C illustrate a laser assisted bonding device according to an embodiment of the present application.

FIGS. 2A to 2C illustrate various steps of a method for bonding a semiconductor die onto a substrate using a compression bonding mechanism according to an embodiment of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature's relationship to another element(s) or feature(s) as illustrated in the Figures. The spatially relative terms are intended to encompass different orientations of the device in use or operation in addition to the orientation depicted in the Figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

As mentioned above, typically, semiconductor dice are first fabricated in wafer level and then each semiconductor die may be attached onto a package substrate after singulation of the semiconductor wafer, to form an integrated semiconductor device. The attaching process of the semiconductor die can be conducted by a bonding device, which can utilize vacuum to pick up and move the semiconductor die on a substrate, and heat solder bumps underneath the semiconductor die to bond the semiconductor die onto the substrate.

However, the inventors of the present application found that when the solder bumps are heated by the bonding device, a temperature distribution across the semiconductor die is in lack of uniformity, which results in warpage issues and adversely affects the performance of the semiconductor device so produced. Furthermore, the inventors found that the nonuniform temperature distribution may be resulting from different vacuum conditions at different positions of the semiconductor die, which are applied by the bonding device when it is in contact with the semiconductor die. Vacuum can be introduced by a vacuum passage of the bonding device from a vacuum source. For example, the temperature of a region of the semiconductor die which is closer to the vacuum passage may be higher than that of another region of the semiconductor die which is farther away from the vacuum passage. The nonuniform temperature distribution may produce a significant thermal stress within the semiconductor die, thereby inducing warpage issues to the semiconductor die.

To address the above issue, a new laser assisted bonding device is provided, which may produce a substantially uniform temperature distribution across a semiconductor die when the semiconductor die and solder bumps are heated during a bonding process, by utilizing a compression head having a plurality of blocks distributed in a gradient pattern. The laser assisted bonding device can be used in a bonding process of a semiconductor die to alleviate warpage issues, especially for semiconductor dice which are easy to warp, for example, due to a composition of heterogeneous materials or a relatively large size.

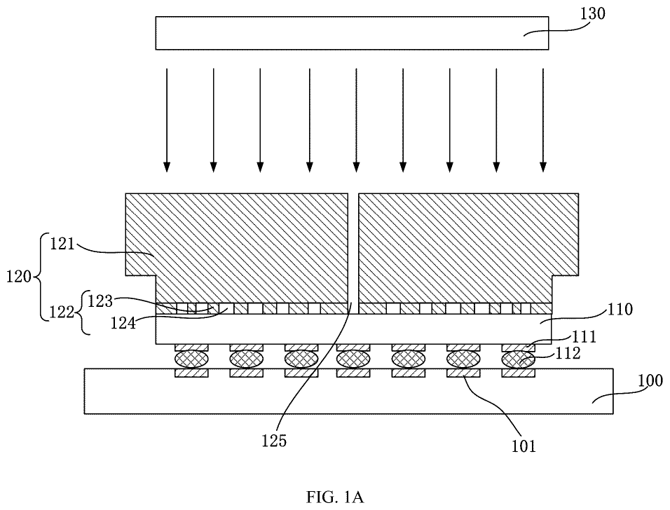

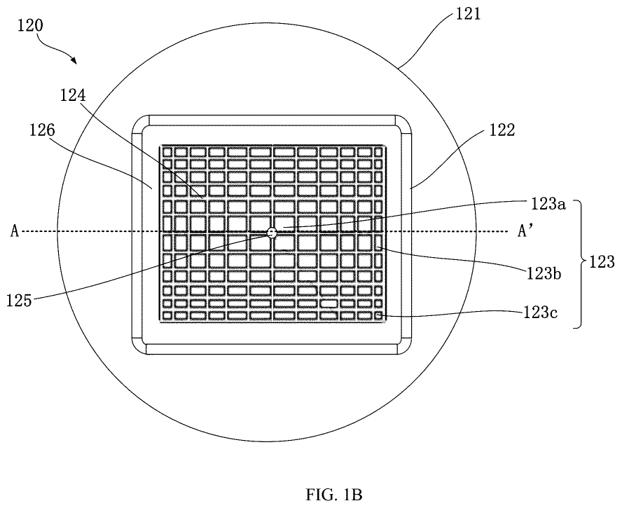

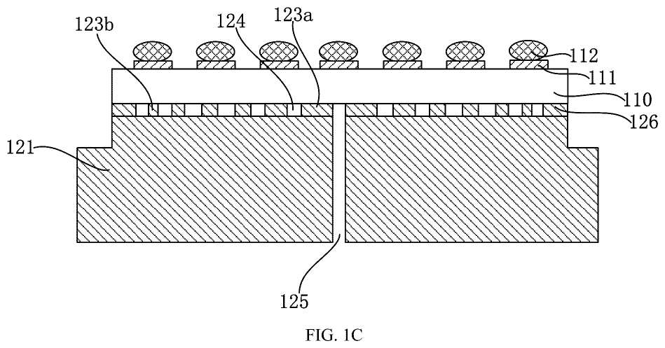

FIGS. 1A to 1C illustrate a laser assisted bonding device according to an embodiment of the present application. In particular, FIG. 1A illustrates a cross-sectional view of the laser assisted bonding device, FIG. 1B illustrates a bottom view of a compression bonding mechanism of the laser assisted bonding device shown in FIG. 1A, and FIG. 1C illustrates a cross-sectional view of the compression bonding mechanism along line AA′ shown in FIG. 1B. To facilitate the understanding, a semiconductor die is attached to the laser assisted bonding device in FIG. 1C.

As shown in FIG. 1A, the laser assisted bonding device is used for conducting a bonding process of a semiconductor die 110 onto a substrate 100. To be more specific, the laser assisted bonding device includes a compression bonding mechanism 120 and a laser source 130. During the bonding process, the compression bonding mechanism 120 is used for picking up the semiconductor die 110, moving the semiconductor die 110 to a bonding position on the substrate 100 and pressing the semiconductor die 110 against the substrate 100. Also during the bonding process, the laser source 130 is used for emitting a laser beam that passes through the compression bonding mechanism 120 to heat solder bumps 112 between the semiconductor die 110 and the substrate 100 (which is referred to as a heating process) to form sufficient bonding between the semiconductor die 110 and the substrate 100 through the solder bumps 112. In some embodiments, a flux material may be disposed on surfaces of the solder bumps 112.

In some embodiments, multiple sets of conductive pads 101 can be formed on a front surface of the substrate 100 for the mounting of the semiconductor die 110 on the substrate 100. It can be appreciated that the multiple sets of conductive pads 101 may be exposed portions of interconnect wires formed within the substrate 100. In some embodiments, additional conductive pads 111 may formed on a bottom surface of the semiconductor die 110 for the mounting of the solder bumps 112.

As shown in FIG. 1B, the compression bonding mechanism 120 includes a compression base 121. In the embodiment, the compression base 121 has a circular layout. In other embodiments, the compression base 121 may have a different shaped layout, such as a rectangle, a hexagon or an octagon, as long as semiconductor dice can be picked up by the compression base 121 during the bonding process. A vacuum passage 125 extends through the compression base 121, and is fluidly connected with a vacuum source. The vacuum passage 125 is further connected with a bottom surface of the compression bonding mechanism 120. During the bonding process, the vacuum source may be activated and vacuum may be formed in the vacuum passage 125 and further at the bottom surface of the compression bonding mechanism 120, which provides a vacuum pressure to pick up the semiconductor die 110 and temporarily attach it onto the bottom surface of the compression bonding mechanism 120. In some embodiments, the vacuum passage 125 may include a control valve for regulating vacuum within the vacuum passage 125. In the embodiment shown in FIGS. 1A to 1C, the vacuum passage 125 is formed in a central region of the compression base 121, which may be efficient to introduce vacuum to the bottom surface of the compression bonding mechanism 120 in a more uniform manner. In some other embodiments, a vacuum passage 125 may be disposed in a marginal region of the compression base 121, or in any other suitable position of the compression base 121.

In some alternative embodiments, apart from the vacuum passage 125, the compression base 121 may further include at least one additional vacuum passage, which extends through the compression base 121 and is fluidly connected with the vacuum source. For example, the compression base 121 may include two additional vacuum passages which are arranged symmetrically at two opposite sides of the vacuum passage 125. The two additional vacuum passages may both be placed away from the vacuum passage 125 that is in the central region of the compression base 121. In this way, the additional vacuum passages may help to apply additional vacuum pressures at multiple positions which are away from the central vacuum passage 125, thereby compensating for attenuation of the vacuum pressure in these marginal regions. In some embodiments, each of the at least one additional vacuum passage may include a control valve which is used for regulating vacuum within the corresponding additional vacuum passage. In some embodiments, the vacuum passage 125 and the at least one additional vacuum passage may be fluidly connected with the same vacuum source, but the control valves within the vacuum passage 125 and the at least one additional vacuum passage may be turned on or off or adjusted separately.

Still referring to FIGS. 1A to 1C, the compression bonding mechanism 120 further includes a compression head 122 which is attached on a bottom surface of the compression base 121. In some embodiments, the size of the compression head 122 may be substantially equal to or smaller than that of the compression base 121, especially a bottom surface of the compression base 121. The compression head 122 may be in contact with the semiconductor die 110 when it is picked up by the compression bonding mechanism 120. In the embodiment shown in FIG. 1B, the compression head 122 may have a rectangular layout, which may be similar to a shape of a semiconductor die. In some other embodiments, the compression head 122 may have other shaped layouts, such as a circle, a hexagon or an octagon. In some embodiments, the compression base 121 may include a protruding platform which may be in direct contact with the compression head 122 and may have a same size or layout that is the same as that of the compression head 122. It can be appreciated that the compression head 122 may be formed separately from the compression base 121, or may be integrally formed with the compression base 121 as a single piece.

Still referring to FIGS. 1A to 1C, the compression head 122 includes a plurality of blocks 123 which are distributed across the compression head 122 and form the bottom surface of the compression bonding mechanism 120. During the bonding process, e.g., when the semiconductor die 110 is picked up or pressed against the substrate 100 by the compression bonding mechanism 120, the plurality of blocks 123 are in contact with the semiconductor die 110, which provide a flat contact surface and sufficient mechanical support for the semiconductor die 110. The compression head 122 further includes a plurality of grooves 124 separating the plurality of blocks 123 from each other and optionally exposing the bottom surface of the compression base 121. The plurality of grooves 124 are fluidly connected with the vacuum passage 125. When the vacuum source is activated, vacuum is formed in the vacuum passage 125 and then in the plurality of grooves 124 through the vacuum passage 125. In this way, the semiconductor die 110 can be firmly attached to the compression head 122 due to the vacuum pressure formed in the grooves 124.

In the embodiment, a size of a block of the plurality of blocks 123 decreases with a distance of the block 123 to the vacuum passage 125. In other words, the farther the distance between the block 123 and the vacuum passage 125 is, the smaller the size of the block 123 is. Here, FIG. 1B clearly shows the bottom surface of the compression head 122 illustrated in FIG. 1A. Referring to FIG. 1B in conjunction with FIGS. 1A and 1C, the plurality of grooves 124 include multiple parallel vacuum lines arranged in both a horizontal direction and a longitudinal direction of the compression head 122, which intersect with each other and form a mesh pattern. Accordingly, the plurality of blocks 123 may also be arranged in both of the horizontal direction and the longitudinal direction to form a grid pattern, and the blocks 123 are separated by the parallel vacuum lines from each other. Each of the blocks 123 may be surrounded by four vacuum lines. The blocks 123 may be sized to follow a gradient grid pattern. That is, the block 123 which has the shortest distance to the vacuum passage 125 has the largest size (e.g., a block 123a closer to the vacuum passage 125 and in the central region), and with the distance from the block 123 to the vacuum passage 125 increases, the size of the block 123 may decrease (e.g., block 123b). Moreover, the sizes of the blocks 123 may decrease with a distance of the block 123 to the vacuum passage 125 in both of the horizontal direction and the longitudinal direction. For example, the block 123a which has the smallest distance to the vacuum passage 125 in both of the horizontal direction and the longitudinal direction may have a largest block size. The block 123c which has the largest distance to vacuum passage 125 in both of the horizontal direction and the longitudinal direction may have a smallest block size. The block 123b which has the smallest distance to the vacuum passage 125 in the longitudinal direction but has the largest distance in the horizontal direction may have a block size smaller than the block 123a but larger than the block 123c. In this way, the space between a pair of adjacent vacuum lines (i.e., adjacent grooves 124) may decrease with a distance of the pair to the vacuum passage 125, which results in a larger surface area of the grooves 124 in per unit region of the compression head 122 in the marginal regions than that in the central region of the compression head 122.

The gradient grid pattern of the blocks 123 helps in forming a uniform temperature distribution across the compression bonding mechanism 120 as well as the semiconductor die attached thereto in a heating process of the semiconductor die 110 and the solder bumps 112 during the bonding process. In particular, the marginal regions of the semiconductor die 110 may be exposed to vacuum grooves 124 with a larger surface area, which may result in a larger vacuum area and therefore a larger vacuum pressure to the semiconductor die 110. This effectively compensates for attenuation of the vacuum pressure from the vacuum passage 125. As a result, the compression bonding mechanism 120 may provide a greater vacuum pressure when picking up and pressing the semiconductor die 110 such that the semiconductor die 110 may be held more securely during the bonding process. In addition, with the marginal regions of the semiconductor die 110 exposed to a larger vacuum area, the semiconductor die 110 may be in contact with the surface of the compression head 122 in a more uniform way with reduced warpage issues, where both of the central region and the marginal regions of the semiconductor die 110 may be applied with sufficient vacuum pressures in the grooves 124 arranged in both of the central region and the marginal regions of the compression head 122. Also, when the semiconductor die 110 is pressed against the substrate 100 by the compression bonding mechanism 120, the solder bumps 112 beneath the semiconductor die 110 may also be pressed uniformly, resulting in better bump planarity, joint quality and higher yield. In some embodiments, each of the plurality of grooves 124 has a same width. In some other embodiments, a width of a groove of the plurality of grooves may increase with a distance of the groove to the vacuum passage 125, which further increases the vacuum area exposed to the marginal regions of the semiconductor die 110.

In some embodiments, the compression head 122 further includes a compression seat 126 which is arranged at or close to a periphery of the compression head 122. The compression seat 126 may surround and provide protection for the blocks 123. In some embodiments, the compression seat 126 may receive the semiconductor die 110 therein, and in some other embodiments such as the embodiment shown in FIG. 1C, the compression seat 126 may have the same height as that of the blocks 123 relative to the compression base 121.

In some other embodiments, the plurality of blocks 123 and the plurality of grooves 124 may form other patterns. For example, the plurality of grooves may include a plurality of concentric annuluses which are connected with each other via channels. The plurality of blocks each between one pair of the pairs of adjacent annuluses may have a decreased size, when a distance from the block to the vacuum passage is getting larger. In some alternative embodiments, the plurality of grooves may include a plurality of straight-flanked rings which are connected with each other via channels.

As aforementioned, two or more vacuum passages may be formed through the compression base 121. In this case, the grooves 124 may be classified into several groups or regions depending on their distances to the respective vacuum passage. The blocks 123 in the same group or region may have varying sizes depending on their distances to the closest one of the vacuum passages, to further compensate for the attenuation of vacuum within the grooves 124 in the margin of the group or region.

In some embodiments wherein multiple vacuum passages exists, an infrared (IR) camera may be integrated within the laser assisted bonding device to monitor the flatness of the semiconductor die 110, especially at its bottom surface, when the semiconductor die 110 is picked up or pressed against the substrate 100. The observation result of the IR camera may help to mitigate the non-flatness of the semiconductor die 110 by turning on or off or adjusting one or more of the control valves of the vacuum passages. For example, when the IR camera observes that the bottom surface of the semiconductor die 110 is lower in the marginal region than in the central region, the control valve(s) of one or more of the additional vacuum passages closest to the marginal region may be turned on or may be adjusted to increase the vacuum pressure therein, to further increase vacuum pressures in the grooves 124 close to the marginal region to avoid warpage issues.

Moreover, still referring to FIG. 1A, the laser assisted bonding device further includes a laser source 130. During the bonding process, e.g., when the semiconductor die 110 is pressed against the substrate 100, the laser source 130 may be turned on to emit a laser beam that passes through the compression bonding mechanism 120, with its optical energy transformed into thermal energy that heats up the semiconductor die 110 and the solder bumps 112 to form joints between the semiconductor die 110 and the conductive pads 101 on the substrate 100. By using the laser source 130 to conduct the heating process of the semiconductor die 110 and the solder bumps 112, no additional reflow process is required, and the heating process may take only a few seconds to bond the semiconductor die 110 and the substrate 100 together. Due to the short duration of the heating process, thermal expansion mismatch in the semiconductor die 110 is much lower than conventional thermal compression bonding process, which results in smaller die warpage and thermal stress. In some embodiments, the laser source 130 can emit a homogenized laser beam, which may improve the uniformity of heat applied to the semiconductor die 110 and the solder bumps 112. In the embodiment, the compression bonding mechanism 120 may include at least one transparent material selected from the following group: sapphire, quartz and glass, which allows the laser beam to efficiently pass through the compression bonding mechanism 120 and reach the semiconductor die 110.

In the embodiment, when the laser beam passes through the compression bonding mechanism 120 and reaches the semiconductor die 110, the temperature of the semiconductor die 110 and the solder bumps 112 may begin to rise. It should be noted that for parts of the semiconductor die 110 which are exposed to a higher level of vacuum pressure, the temperature rise may be higher. This may be caused by tighter contact between the semiconductor die 110 and the compression head 122 which facilitates energy transfer from the laser beam to the semiconductor die 110. Also, the higher level of vacuum pressure may also facilitate energy transfer by radiation due to reduced heat loss in the vacuum condition. Therefore, a larger vacuum area exposed to the marginal region of the semiconductor die 110 due to a gradient pattern of the blocks 123 allows for a sufficient heating process of the marginal region of the semiconductor die 110 as well as that of the central region, which results in a uniform temperature distribution across the whole semiconductor die 110 as well as reduced warpage issues during or after the heating process.

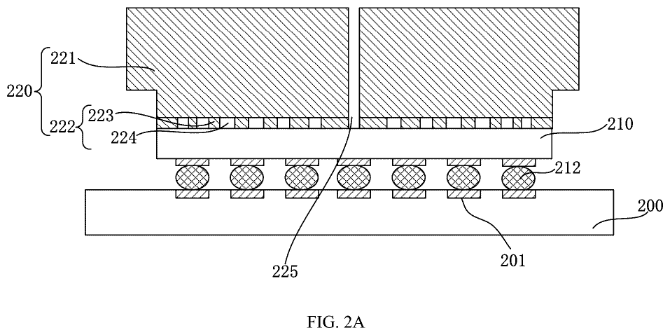

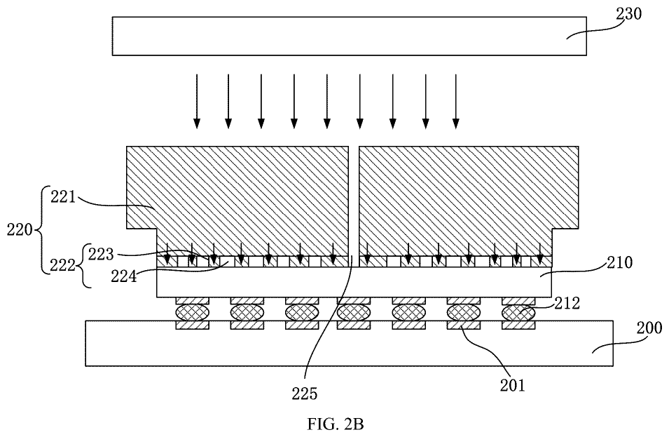

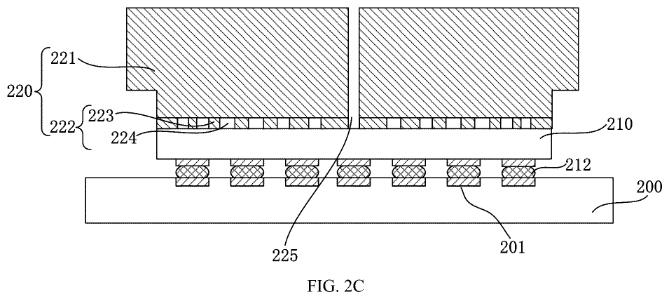

FIGS. 2A to 2C illustrate various steps of a method for bonding a semiconductor die 210 onto a substrate 200 using a compression bonding mechanism 220 according to an embodiment of the present application.

As shown in FIG. 2A, a substrate 200 having a front surface is provided. For example, the substrate 200 may be placed on a carrier. The front surface of the package substrate 200 may serve as a platform where semiconductor die (dice) can be mounted. Multiple sets of conductive pads 201 can be formed on the front surface of the substrate 200 for the mounting of the semiconductor die (dice). It can be appreciated that the multiple sets of conductive pads 201 may be exposed portions of interconnect wires formed within the substrate 200. In addition, at least one semiconductor die 210 is provided with solder bumps 212 mounted on a bottom surface of the semiconductor die 210. In some other embodiments, the solder bumps 212 may first be mounted on the substrate 200 for mounting of the semiconductor die 210. In some embodiments, a flux material may be disposed on surfaces of the solder bumps 212.

Next, a compression bonding mechanism 220 is used to pick up the semiconductor die 210. The compression bonding mechanism 220 may be the same as the compression bonding mechanism 120 illustrated in FIGS. 1A to 1C. To be more specific, the compression bonding mechanism 220 may be first moved down towards the semiconductor die 210 until a compression head 222 is in contact with the semiconductor die 210. Next, a vacuum source may be activated to apply vacuum in a vacuum passage 225, and then a vacuum pressure may be formed in a plurality of grooves 224 through the vacuum passage 225. Therefore, the semiconductor die 210 may be attached onto the compression head 222 due to the vacuum pressure in the grooves 224. Next, the compression bonding mechanism 220 is displaced to move the semiconductor die 210 to a pre-bonding position above the substrate 200, and then the compression bonding mechanism 220 can be further moved down towards the substrate 200 until the solder bumps 212 are in contact with the substrate 200, i.e., in a bonding position where the semiconductor die 210 can be bonded to the substrate 200. Next, the compression bonding mechanism 220 may be held for some time to wait for stabilization of the semiconductor die 210.

Next, as shown in FIG. 2B, a laser beam is emitted to the semiconductor die 210 through the compression bonding mechanism 220 via a laser source 230, which heats the semiconductor die 210 and solder bumps 212 between the semiconductor die 210 and the substrate 200. During the heating process, the compression head 222 is in contact with the semiconductor die 210 due to the vacuum maintained in the plurality of grooves 224 which securely holds the semiconductor die 210 with the compression head 222. The temperature of the semiconductor die 210 and solder bumps 212 may gradually increase, and the solder bumps 212 may start to melt and infiltrate on the conductive pads 201 within the substrate 200.

At the same time, the compression bonding mechanism 220 may press the semiconductor die 210 against the substrate 200 to reshape the solder bumps 212 when or after they are heated. During the pressing process, the compression head 222 is in contact with the semiconductor die 210 due to the vacuum pressure in the grooves 224. A press force applied by the compression bonding mechanism 220 may be increased gradually until the solder bumps 212 are fully infiltrated on the conductive pads 201 within the substrate 200 and are reshaped to form respective joints or electrical connection between the semiconductor die 210 and the substrate 200. Next, the press force applied by the compression bonding mechanism 220 may gradually decrease to allow for stabilization of the solder bumps 212.

Next, as shown in FIG. 2C, after the joints between the semiconductor die 210 and the substrate 200 are formed, the laser source 230 may be turn off. Then the heating process of the semiconductor die 210 and the solder bumps 212 is terminated, and the temperature of the semiconductor die 210 and the solder bumps 212 may begin to decrease to a lower temperature such as room temperature. The force applied by the compression bonding mechanism 220 may also be removed and the shapes of the solder bumps 212 may not change, which enables stable joints between the semiconductor die 210 and the substrate 200 and thereby completes the bonding process.

In the embodiment, the bonding process of a semiconductor die 210 conducted by the compression bonding mechanism 220 may provide several advantages. Firstly, a larger vacuum area is exposed to the marginal regions of the semiconductor die 210 due to a gradient pattern of the blocks 223, which effectively compensates for attenuation of the vacuum pressure from the vacuum passage 225. Therefore, when the semiconductor die 210 is picked up and pressed against the substrate 200, the compression bonding mechanism 220 may provide a greater vacuum pressure such that the semiconductor die 210 may be held more securely. Secondly, the semiconductor die 210 may be in contact with the surface of the compression head 222 in a more uniform way with reduced warpage issues, where both of the central region and marginal regions of the semiconductor die 210 may be applied with sufficient vacuum pressures in the grooves 224. Thirdly, when the semiconductor die 210 is pressed against the substrate 200 by the compression bonding mechanism 220, the solder bumps 212 beneath the semiconductor die 210 may also be pressed uniformly, which allows for better bump planarity, better joint quality and higher yield. Finally, the compression bonding mechanism 220 allows for a sufficient heating process of the marginal regions of the semiconductor die 210 as well as that of the central region, thereby allowing for a uniform temperature distribution across the whole semiconductor die 210 as well as reduced warpage issues during or after the heating process.

While the exemplary laser assisted bonding device of the present application is described in conjunction with corresponding figures, it will be understood by those skilled in the art that modifications and adaptations to laser assisted bonding device may be made without departing from the scope of the present invention.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A laser assisted bonding device, comprising:
a compression bonding mechanism configured for picking up a semiconductor die and pressing the semiconductor die against a substrate, wherein the compression bonding mechanism comprises:
a compression base comprising a vacuum passage extending through the compression base and fluidly connected with a vacuum source; and
a compression head attached to the compression base, wherein the compression head comprises a plurality of blocks distributed across the compression head and being in contact with the semiconductor die when the semiconductor die is picked up or pressed against the substrate by the compression bonding mechanism, and a plurality of grooves separating the plurality of blocks from each other and being fluidly connected with the vacuum passage to form vacuum in the plurality of grooves, and wherein a size of a block of the plurality of blocks decreases with a distance of the block to the vacuum passage; and
a laser source configured for emitting a laser beam that passes through the compression bonding mechanism to heat solder bumps between the semiconductor die and the substrate.

2. The device of claim 1, wherein the vacuum passage is disposed in a central region of the compression base.

3. The device of claim 1, wherein the plurality of blocks form a grid pattern.

4. The device of claim 1, wherein each of the plurality of grooves has a same width.

5. The device of claim 1, wherein a width of a groove of the plurality of grooves increases with a distance of the groove to the vacuum passage.

6. The device of claim 1, wherein the compression base further comprises at least one additional vacuum passage extending through the compression base and fluidly connected with the vacuum source, and at least one of the grooves is fluidly connected with the additional vacuum passage.

7. The device of claim 6, wherein each of the vacuum passage and the at least one additional vacuum passage comprises a control valve configured for regulating a vacuum pressure within the vacuum passage or the at least one additional vacuum passage.

8. The device of claim 1, wherein the compression bonding mechanism comprises at least one transparent material selected from the following group: sapphire, quartz and glass.

9. The device of claim 1, wherein the laser source is configured for emitting a homogenized laser beam.

10. A method for bonding a semiconductor die onto a substrate using a compression bonding mechanism, wherein the compression bonding mechanism comprises a compression base having a vacuum passage extending through the compression base and fluidly connected with a vacuum source, and a compression head attached to the compression base, wherein the compression head comprises a plurality of blocks distributed across the compression head, and a plurality of grooves separating the plurality of blocks from each other and being fluidly connected with the vacuum passage to form vacuum in the plurality of grooves, and wherein a size of a block of the plurality of blocks decreases with a distance of the block to the vacuum passage, the method comprising:
picking up the semiconductor die via the compression bonding mechanism by activating the vacuum source and applying vacuum in the plurality of grooves through the vacuum passage, wherein the compression head is in contact with the semiconductor die;
displacing the compression bonding mechanism to place the semiconductor die on the substrate;
pressing the semiconductor die against the substrate while vacuum is maintained in the plurality of grooves, wherein the compression head is in contact with the semiconductor die; and
emitting a laser beam to the semiconductor die through the compression bonding mechanism via a laser source to heat solder bumps between the semiconductor die and the substrate.

11. The method of claim 10, wherein the vacuum passage is disposed in a central region of the compression base.

12. The method of claim 10, wherein the plurality of blocks form a grid pattern.

13. The method of claim 10, wherein the compression base further comprises at least one additional vacuum passage extending through the compression base and fluidly connected with the vacuum source, and at least one of the grooves is fluidly connected with the additional vacuum passage, the method further comprising:
applying vacuum in the at least one of the grooves through the at least one additional vacuum passage.

14. The method of claim 13, wherein each of the vacuum passage and the at least one additional vacuum passage comprises a control valve, and applying vacuum in the plurality of grooves through the vacuum passage and the at least one additional vacuum passage further comprises: regulating a vacuum pressure within the vacuum passage or the at least one additional vacuum passage via the corresponding control valve.
